(19) United States
(12) Patent Application Publication
(10) Pub. No.: US 2026/0204527 A1
(43) Pub. Date: Jul. 16, 2026

(54) Arc Analysis Based On Multiple Engineered Arc Detection Sources And State Data

(71) Applicant: MKS, Inc., Andover, MA (US)

(72) Inventors: Aaron SWENSON, Rochester, NY (US); Deyasini MAJUMDAR, Rochester, NY (US); Jesse KLEIN, Rochester, NY (US); Peter PAUL, Rochester, NY (US); Aaron RADOMSKI, Rochester, NY (US); Aaron BURRY, Rochester, NY (US); Vladimir KOZITSKY, Rochester, NY (US); Jonathan SMYKA, Rochester, NY (US)

(21) Appl. No.: 19/023,750

(22) Filed: Jan. 16, 2025

(51) Int. Cl. H01J 37/32

(52) U.S. Cl. CPC H01J 37/32944; H01J 2237/24564

(57) ABSTRACT

A controller for an arc detection system includes at least one arc detector module configured to output at least one arc detection signal in a plasma processing system. An arc analysis module is configured to receive the at least one arc detection signal, to determine if at least one arc is present in the plasma processing system based on the at least one arc detection signal, and to generate an arc mitigation signal in accordance with the at least one arc.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a controller for arc detection. The controller also includes at least one arc detector module configured to output at least one arc detection signal in a plasma processing system. The controller also includes an arc analysis module configured to receive the at least one arc detection signal, to determine if at least one arc is present in the plasma processing system based on the at least one arc detection signal, and to generate an arc mitigation signal in accordance with the at least one arc. Other embodiments of this aspect include corresponding computer systems, apparatus, and computer programs recorded on one or more computer storage devices, each configured to perform the actions of the methods.

Implementations may include one or more of the following features. The controller may include a state data module configured to obtain information about at least one state of the plasma processing system, where the arc analysis module determines if the at least one arc is present in the plasma processing system additionally based on the at least one state of the plasma processing system. The information about at least one state of the plasma processing system may include at least one of current or historical data related to one or more measured or commanded power levels, measured or commanded pulsing information, pulse repetition rate, pulse duty cycle, pulse ramp rate between setpoints, timestamp information, recipe information, pulsed dc frequency, pulsed dc duty cycle, control loop statistics, recipe data, data shared between multiple power generators or power sources of a plasma processing system, and matching network data. The controller may include an arc mitigation module configured to receive commands from the arc analysis module and generate commands to at least one of mitigate the at least one arc or indicate a fault, or take no action. The arc mitigation module at least one of commands an adjustment to an electrical component of the plasma processing system, indicates a system fault, or engages a protection circuit. The at least one arc detector module is configured to output the arc detection signal in accordance with at least one sensed, measured, or determined electrical parameter or characteristic of the plasma processing system, including at least one of voltage, current, reverse power, forward power, active power, reactive power, gradients of at least one of voltage, current, energy, gradients of at least one of power, reverse power, forward power, active power, or reactive power, reflection coefficient, or a square of a magnitude of a reflection coefficient. The at least one arc detector module includes a plurality of arc detection sources, where the at least one arc detection signal includes a plurality of arc detection signals and each one of the plurality of arc detection sources generates a respective one of the plurality of arc detection signals. The arc analysis module assigns a weight to each arc detection signal of the plurality of arc detection signals, and the weights of the plurality of arc detection signals are one of compared, tallied, or accumulated to determine whether to respond to the at least one arc. The arc analysis module is configured to determine whether to respond to the determination that at least one arc is present in accordance with the arc detection signal and information about at least one state of the plasma processing system. The at least one arc includes a pair of arcs and the arc analysis module determines a time between the pair of arcs and triggers arc mitigation if the time is less than a predetermined time. Implementations of the described techniques may include hardware, a method or process, or computer software on a computer-accessible medium.

One general aspect includes a non-transitory computer-readable medium storing instructions. The non-transitory computer-readable medium storing instructions also includes obtaining at least one arc detection signal in a plasma processing system. The instructions also include receiving the at least one arc detection signal, determining if at least one arc is present in the plasma processing system based on the at least one arc detection signal, and generating an arc mitigation signal in accordance with the at least one arc. Other embodiments of this aspect include corresponding computer systems, apparatus, and computer programs recorded on one or more computer storage devices, each configured to perform the actions of the methods.

Implementations may include one or more of the following features. The non-transitory computer-readable medium storing instructions, the instructions may include obtaining information about at least one state of the plasma processing system, where determining if the at least one arc is present in the plasma processing system is additional based on the at least one state of the plasma processing system. The information about at least one state of the plasma processing system may include at least one of current or historical data related to one or more measured or commanded power levels, measured or commanded pulsing information, pulse repetition rate, pulse duty cycle, pulse ramp rate between setpoints, timestamp information, recipe information, pulsed dc frequency, pulsed dc duty cycle, control loop statistics, recipe data, data shared between multiple power generators or power sources of a plasma processing system, and matching network data. The non-transitory computer-readable medium storing instructions the instructions may include receiving the arc mitigation signal and generating commands to at least one of mitigate the at least one arc or indicate a fault, or take no action. Mitigating the at least one arc further may include at least one of commanding a power adjustment to an electrical component of the plasma processing system or engaging a protection circuit. The at least one arc detection signal varies in accordance with at least one sensed, measured, or determined electrical parameter or characteristic of a plasma processing system including at least one of voltage, current, reverse power, forward power, active power, reactive power, gradients of at least one of voltage, current, energy, gradients of at least one of power, reverse power, forward power, active power, or reactive power, reflection coefficient, or a square of a magnitude of a reflection coefficient. The at least one arc detection signal includes a plurality of arc detections signals and the instructions further may include instructions for obtaining the plurality of arc detection signals using two different approaches. The instructions further may include instructions for assigning a weight to each arc detection signal of the plurality of arc detection signals and for one of comparing, tallying, or accumulating the weights to determine whether to respond to the at least one arc. The instructions further may include determining whether to respond to the determination that at least one arc is present in accordance with the arc detection signal and information about at least one state of the plasma processing system. The at least one arc includes a pair of arcs, and the instructions further may include instructions for determining a time between the pair of arcs and triggering arc mitigation if the time is less than a predetermined time. Implementations of the described techniques may include hardware, a method or process, or computer software on a computer-accessible medium.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 shows a generalized representation of a plasma system arranged according to various configurations of the present disclosure;

FIG. 2 is a diagram classifying various arcs that can occur in a plasma generation system;

FIG. 3 is a schematic block diagram of a power delivery system having multiple power supplies arranged according to various configurations of the present disclosure;

FIG. 4 is a schematic block diagram of an arc detection and mitigation system in accordance with the present disclosure;

FIG. 5 shows a functional block diagram of an example control module arranged in accordance with various configurations; and

FIG. 6 shows a flow chart of operation of a control system arranged in accordance with the principals of the present disclosure.

In the drawings, reference numbers may be reused to identify similar and/or identical elements.

### DETAILED DESCRIPTION

A power system may include a DC or RF power generator or DC or RF generator, collectively referred to as generator or generators, a matching network, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. Impedance matching aids in maximizing an amount of power delivered to the load (“delivered power”) and minimizing an amount of power reflected back from the load to the generator (“reverse power” or “reflected power”). Delivered power may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous voltage, current, or power signal to the load. In a continuous mode or continuous wave mode, a continuous voltage, current, or power signal is typically a constant DC, sinusoidal, or periodic time-varying signal, which may be a RF or other voltage, current, or power signal, which is output continuously by the power source to the load. In the continuous mode approach, the voltage, current, or power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal or carrier signal is modulated by a modulation signal in order to define an envelope for the modulated power signal. The voltage, current, or power signal may be, for example, a sinusoidal RF signal or other periodic or nonperiodic time-varying signal. Power delivered to the load is typically varied by varying the modulation signal. In a pulsed mode of operation of a pulsed DC signal, the voltage, current, or power signal may be a periodic or nonperiodic DC signal that alternates between at least a first amplitude and a second amplitude over one or more cycles and modulated by a modulation signal in order to define an envelope for the pulsed DC signal. In various configurations, a transition between the first amplitude and the second amplitude may include various shapes, including vertical slopes, nonvertical slopes, or combinations thereof, stair steps, and the like. Further the transition between the first amplitude and the second, or the second amplitude and the first amplitude, may be consistent or vary from cycle.

In one various power supply configuration, output voltage, current, or power applied to the load is determined using sensors that measure the forward and reflected voltage, current, or power signal. Either set of these signals is analyzed in a control loop. The analysis typically determines parameter or a cost function that varies in accordance with a voltage, current, or power value and is used to adjust the output of the power supply in order to vary the voltage, current, or power applied to the load. In a power delivery system where the load is a process chamber or other nonlinear or time-varying load, the varying impedance of the load causes a corresponding varying of voltage, current, or power applied to the load and consequent varying of the parameter or cost function, as applied voltage, current, or power is in part a function of the impedance of the load.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

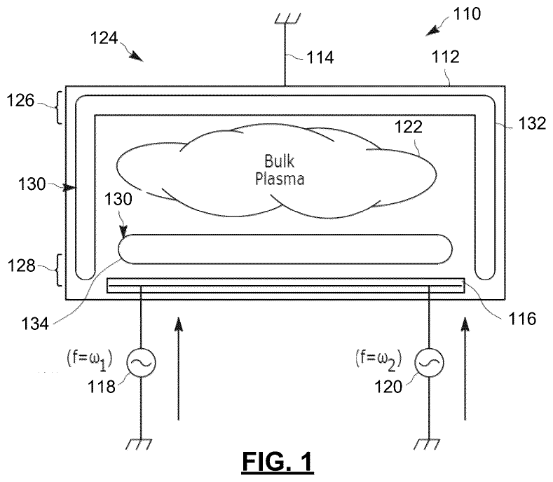

FIG. 1 depicts a cross-sectional view of a generalized representation of a dual voltage, current, or power input plasma system 110. Plasma system 110 includes first electrode 112, a wall of plasma chamber 124, connected to ground 114 and second electrode 116 spaced apart from first electrode 112. A voltage, current, or power supply; voltage, current, or power source; RF power generator; or RF power source 118, 120 (the terms may be used herein interchangeably to refer to an appropriately configured voltage, current, or power supply, source, or generator) applies power to plasma chamber 112 via second electrode 116. A first power source 118 generates a first voltage, current, or power signal as described above, applied to second electrode 116 at a first frequency ƒ=ω₁. A second power source 120 generates a second DC (ω=0) or sinusoidal voltage, current, or power applied to second electrode 116. In various configurations, first power source

118 operates at a frequency ƒ=ω₁, where ω₁=nω₂ that is the n^{th} harmonic frequency of the frequency of second power source 120. In various other configurations, first power source 118 and second power source 120 operate at frequencies that are not multiples. In various configurations, power sources 118, 120 are locked to operate at the same frequency, with fixed or varying relative phases. In various other configurations, power sources 118, 120 may operate at different frequencies, voltages, currents, or powers, and relative phases. In other various configurations, first power source 118 and second power source 120 may be synchronously or asynchronously pulsed to modulate an underlying carrier signal, where the respective pulse or pulsed waveforms may have one or a plurality of states and various sinusoidal, nonsinusoidal, and repeating, or nonrepeating shapes.

In various configurations power source 118 outputs a source waveform to ignite or generate plasma 122 or control the plasma density, and power source 120 outputs a bias waveform that modulates the ions to control the ion potential or ion energy of the plasma 122. In various configurations the source waveform or bias waveform may be a sinusoidal or continuous wave signal. In other various configurations, source waveform or bias waveform may be a pulsed sinusoidal, nonsinusoidal, or direct current (DC) signal, having one or more of a varying amplitude, frequency, or duty cycle, as will be described in great detail herein. Further, by way of nonlimiting example, the bias waveform may be a RF waveform, a pulsed RF waveform, a DC waveform, a pulsed DC waveform, a pulsed rectangular waveform, or a piecewise linear waveform. A piecewise linear waveform is described in U.S. Pat. No. 10,396,601, issued on Aug. 27, 2019, entitled Piecewise RF Power Systems and Methods for Supplying Pre-Distorted RF Bias Voltage Signals to an Electrode in a Processing Chamber, assigned to the assignee of the present application, and incorporated by reference herein. In various configurations, a radio frequency (RF) signal may be considered as having a frequency in the range of approximately 2 kHz to 300 GHz.

In various configurations, bias voltage, current, or power and source voltage, current, or power may be applied to the lower electrode, such as second electrode 116 in various combinations. In another nonlimiting example, one of bias voltage, current, or power and source voltage, current, or power may be applied to second electrode 116, and the other of bias voltage, current, or power and source voltage, current, or power may be applied to another electrode (not shown). In various configurations, power sources 118, 120 can be connected to the same electrode, while a counter electrode may be connected to ground 114 or to yet a third DC (ω=0), or other voltage, current, or sources having one or more of a varying amplitude, frequency, or duty cycle power generator (not shown), including, but not limited to, a RF signal. Further, in various configurations, voltage, current, or power may be coupled to plasma chamber 124 using an inductively coupled plasma (ICP) or a capacitively coupled plasma (CCP), as described above.

Coordinated operation of respective power sources 118, 120 results in generation and control of plasma 122. As shown in FIG. 1 in schematic view, plasma 122 is formed within an asymmetric sheath 130 of plasma chamber 124. Sheath 130 includes a ground or grounded sheath 132 and a powered sheath 134. A sheath is generally described as the surface area surrounding plasma 122. As can be seen in schematic view in FIG. 1, grounded sheath 132 has a relatively large surface area 126. Powered sheath 134 has a small surface area 128. Because each sheath 132, 134 functions as a dielectric between the conductive plasma 122 and respective electrodes 112, 116, each sheath 132, 134 forms a capacitance between plasma 122 and respective electrodes 112, 116.

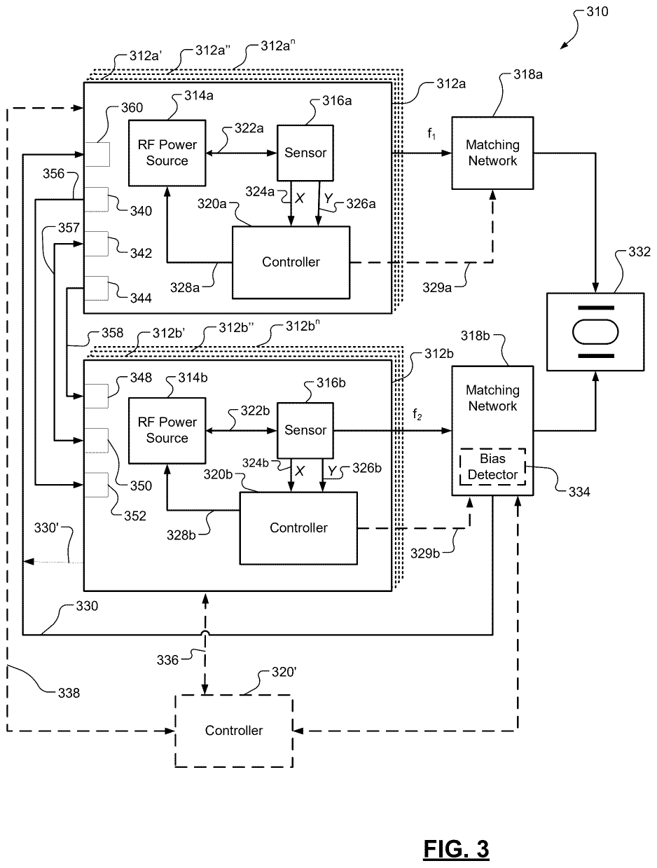

Operation of plasma system 110 of FIG. 1 can sometimes cause an unintended discharge of electric current or voltage across a gap in an electrical circuit or between components of plasma system 110. The discharge may be sustained by the presence of a medium where the arc occurs that continues to enable current or voltage to flow. With reference to FIG. 1, an arc may occur in various locations throughout plasma system 110. For example, an arc may occur in association with operation of RF power generators 118, 120, though it should be understood that while FIG. 1 is described in connection with a pair of RF power generators 118, 120, plasma system 110 may be operated in connection with only one of RF power generators 118, 120 or multiples of one or both of RF power generators 118, 120. Arcs that may occur in connection with operation of RF power generators 118, 120 can include arcs occurring within RF power generators 118, 120, arcs occurring within a cable connecting RF power generators 118, 120 to plasma chamber 124 directly or to a matching network (described in connection with FIG. 3, below) interposed between RF power generators 118, 120 and a plasma chamber 124. In various configurations, arcs may occur within plasma chamber 124, such as when electrical energy is discharged through a circuit including conductive components associated with the plasma chamber. In various other configurations, arcs may occur within plasma 122 when conductive particles within plasma 122 provide a path through which electrical energy may flow.

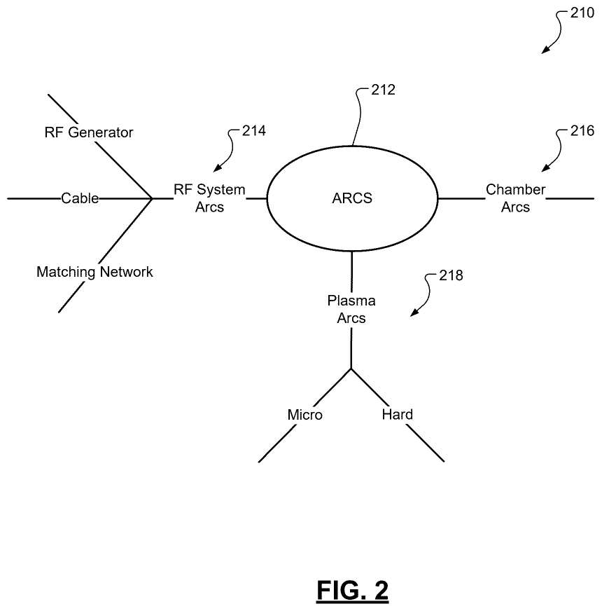

FIG. 2 shows an arc taxonomy 210 that lists classes of arcs and arcing events that occur within the respective classes. In arc taxonomy 210, the arcs are most generally classified as arcs 212. Arcs 212 includes three classifications of arcs, namely, RF system arcs 214, chamber arcs 216, and plasma arcs 218. RF system arcs 214 include one or multiples of arcs occurring within the RF generator, the matching network, or cables interconnecting one or more of the RF generator, the matching network, or the plasma chamber. Example RF system arcs may be associated with RF generators 118, 120 of FIG. 1. Arcs 216 may be generally referred to as chamber arcs and involve conduction to a wall of the plasma chamber. Arcs 218 are generally referred to as plasma arcs and include one or more of micro arcs and hard arcs and occur within the plasma. Hard arcs and micro arcs typically occur in different locations in a plasma system and vary in intensities. Hard arcs tend to occur on the equipment, such as the chuck, edge ring, matching network, and the like. Micro arcs tend to occur on the substrate or within the plasma volume. Hard arcs are of higher intensity and typically require immediate mitigation to protect system components. Micro arcs of lesser intensity, but can negatively impact quality with repeated occurrences.

Electrical arcs that occur during the semiconductor manufacturing process can adversely impact both semiconductor manufacturing equipment and product, such as wafers, integrated circuits, or memory chips being manufactured, potentially resulting in significantly increased costs. When an arc occurs, it is desirable to continue the manufacturing process without interruption or damage to manufacturing equipment or product being manufactured, regardless of the arc events. Present detection and mitigation techniques are tuned to specific types of arcs. Conventionally, each approach to detecting specific types of arcs works independently and does not cooperate with other arc detection techniques deployed within the same semiconductor manufacturing system.

Conventional arc detection systems tend to be narrowly focused such that each of the arcs referenced in FIG. 2 require a specific approach to detecting each respective arc. Present approaches use a specifically designed detection source to determine if an arc is occurring. Present approaches are further limited by relying almost exclusively on contextual data specifically provided to the single detection source. By way of nonlimiting example, hard arcs may require RF output to cease, while micro arcs may be mitigated or stifled with temporary reduction in RF power. In various nonlimiting examples, some arcs may require an increase in voltage, current, or power. Thus, present approaches limit arc detection and mitigation schemes by requiring that each scheme target a specific type of arc, such as the arcs described in connection with FIG. 2.

The present disclosure is directed to expanding the capabilities of arc detection and mitigation by having multiple engineered detection sources cooperating at the same time for enhanced detection capabilities. In various configurations, general generator state data may be used to further enhance arc detection. The enhanced detection allows for more specific mitigation, and generally increases the probability of being able to maintain the manufacturing process without interruption or damage.

FIG. 3 depicts a RF generator or power supply system 310. Power supply system 310 includes a pair of radio frequency (RF) generators or power supplies 312a, 312b, matching networks 318a, 318b, and load 332, such as a nonlinear load, which may be a plasma chamber, plasma reactor, process chamber, and the like. In various configurations, generator 312a is referred to as a source generator or power supply, and matching network 318a is referred to as a source matching network. Further, in various configurations, one or both of voltage, current, or power generators or power supplies 312a, 312b may output a continuous or pulsed time-varying voltage, current, or power signal or a continuous or pulsed DC voltage, current, or power signal. Also in various configurations, generator 312b is referred to as a bias generator or power supply, and matching network 318b is referred to as a bias matching network. It will be understood that components can be referenced individually or collectively using the reference number with or without a letter subscript or a prime symbol. In various configurations, one or both of matching networks 318a, 318b may be implemented as a RF blocking filter, rather than an impedance match, such as may be the case for a matching network receiving a pulsed DC or nonsinusoidal signal. In various other configurations, one or both of matching networks 318a, 318b may be omitted.

In various configurations, source generator 312a receives a control signal 330 from matching network 318b, generator 312b, or a control signal 330′ from bias generator 312b. Control signals 330 or 330′ represent an input signal to source generator 312a that indicates one or more operating characteristics or parameters of bias generator 312b. In various configurations, a synchronization bias detector 334 senses the signal output from matching network 318b to load 332 and outputs synchronization or trigger signal 330 to source generator 312a. In various configurations, synchronization or trigger signal 330′ may be output from bias generator 312b to source RF generator 312a, rather than trigger signal 330. A difference between trigger or synchronization signals 330, 330′ may result from the effect of matching network 318b, which can adjust the phase between the input signal to and output signal from matching network. Signals 330, 330′ include information about the operation of bias RF generator 312b that in various configurations enables predictive responsiveness to address periodic fluctuations in the impedance of plasma chamber or load 332 caused by the bias generator 312b. When control signals 330 or 330′ are absent, generators 312a, 312b operate autonomously.

Generators 312a, 312b include respective power sources or amplifiers 314a, 314b, sensors 316a, 316b, and processors, controllers, or control modules 320a, 320b. Power sources 314a, 314b generate respective voltage, current, or power signals 322a, 322b, various configurations of which are described above, output to respective sensors 316a, 316b. RF power signals 322a, 322b. Signals 322a, 322b pass through sensors 316a, 316b and are provided to matching networks 318a, 318b as respective power signals ƒ₁ and ƒ₂. Sensors 316a, 316b output signals that vary in accordance with various parameters sensed from load 332. While sensors 316a, 316b, are shown within respective generators 312a, 312b, sensors 316a, 316b can be located externally to generators 312a, 312b. Such external sensing can occur at the output of the generator, at the input of an impedance matching device located between the generator and the load, or between the output of the impedance matching device (including within the impedance matching device) and the load.

Sensors 316a, 316b detect various operating parameters and output signals X and Y. Sensors 316a, 316b may include voltage, current, and/or directional coupler sensors. Sensors 316a, 316b may detect (i) voltage V and current I and/or (ii) forward power P_{FWD} output from respective power amplifiers 314a, 314b and/or RF generators 312a, 312b and reverse or reflected power P_{REV} received from respective matching networks 318a, 318b or load 332 connected to respective sensors 316a, 316b. The voltage V, current I, forward power P_{FWD}, and reverse power P_{REV} may be scaled, filtered, or scaled and filtered versions of the actual voltage, current, forward power, and reverse power associated with the respective power sources 314a, 314b. Sensors 316a, 316b may be analog or digital sensors or a combination thereof. In a digital implementation, the sensors 316a, 316b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 316a, 316b generate sensor signals X, Y, which are received by respective controllers or control modules 320a, 320b. Control modules 320a, 320b process the respective X, Y signals 324a, 326a and 324b, 326b and generate one or a plurality of feedforward or feedback control signals 328a, 328b to respective power sources 314a, 314b. Power sources 314a, 314b adjust voltage, current, or power signals 322a, 322b based on the received one or plurality feedback or feedforward control signal. In various configurations, control modules 320a, 320b may control matching networks 318a, 318b, respectively, via respective control signals 329a, 329b based on, for example, X, Y signals 324a, 326a and 324b, 326b. Control modules 320a, 320b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 320a, 320b may include functions, processes, processors, or submodules. Control signals 328a, 328b may be control or actuator drive signals and may communicate DC offset or rail voltage, voltage or current magnitude, frequency, and phase components, and the like. In various configurations, feedback control signals 328a, 328b can be used as inputs to one or multiple control loops. In various configurations, the multiple control loops can include a proportional-integral (PI), proportional-integral-derivative (PID) controllers, linear quadratic regulator (LQR) control loops, or subsets thereof, for RF drive, and for power supply rail voltage. In various configurations, control signals 328a, 328b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 328a, 328b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 310 can include controller 320′. Controller 320′ may be disposed externally to either or both of generators 312a, 312b and may be referred to as external or common controller 320′. In various configurations, controller 320′may implement one or a plurality of functions, processes, or algorithms described herein with respect to one or both of controllers 320a, 320b. Accordingly, controller 320′ communicates with respective generators 312a, 312b via a pair of respective links 336, 338 which enable exchange of data and control signals, as appropriate, between controller 320′ and generators 312a, 312b. For the various configurations, controllers 320a, 320b, 320′ can distributively and cooperatively provide analysis and control of generators 312a, 312b. In various other configurations, controller 320′ can provide control of generators 312a, 312b, eliminating the need for the respective local controllers 320a, 320b.

In various configurations, power source 314a, sensor 316a, controller 320a, and matching network 318a can be referred to as source RF power source 314a, source sensor 316a, source controller 320a, and source matching network 318a, respectively. Similarly in various configurations, RF power source 314b, sensor 316b, controller 320b, and matching network 318b can be referred to as bias power source 314b, bias sensor 316b, bias controller 320b, and bias matching network 318b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, in addition to or by way of partial or total substitution to the synchronization signals described above with respect to signals 330, 330′, source generator 312a and bias generator 312b include multiple ports to communicate with each other and with external devices. Source generator 312a includes pulse synchronization port 340, communication port 342, RF port 344, and control signal port 360. Bias generator 312b includes RF port 348, digital communication port 350, and pulse synchronization port 352. Pulse synchronization port 340 of source generator 312a communicates pulse synchronization signals via link 356 with pulse synchronization port 352 of bias generator 312b. Communication port 342 of source generator 312a and communication port 350 of bias generator 312b communicate data and information via a communication link 357. RF port 344 of source generator 312a communicates with RF port 348 via communication link 358. Control signal port 360 of source generator 312a receives one or both of control signals 330, 330′, as described above. In various configurations, one or more of the ports described above may communicate with matching network 318 for communicating sensed or control signals, as may be described herein.

In various configurations, communication between pulse synchronization port 340 and pulse synchronization port 352 may be unidirectional or bidirectional between source generator 312a and bias generator 312b. In various configurations, one of source generator 312a and bias generator 312b communicate, by way of nonlimiting example, envelope pulse information to the other of bias generator 312b and source generator 312a. In various configurations, one or multiple communication links 356 link pulse synchronization port 340 and pulse synchronization port 352. In various configurations, communication between pulse synchronization port 340 and pulse synchronization port 352 may occur via analog or digital communication.

In various configurations, communication between communication port 342 of source generator 312a and communication port 350 of bias generator 312b may be unidirectional or bidirectional between source generator 312a and bias generator 312b. In various configurations, communication port 342 of source generator 312a and communication port 350 of bias generator 312b communicate, by way of nonlimiting example, data, information, or synchronization signals. In various configurations, one or multiple communication links 357 link pulse synchronization port 342 and pulse synchronization port 350 In various configurations, communication between pulse synchronization port 342 and pulse synchronization port 350 may occur via analog or digital communication.

In various configurations, communication between RF port 344 of source generator 312a and RF port 348 of bias generator 312b may be unidirectional or bidirectional between source generator 312a and bias generator 312b. In various configurations, RF port 344 of source generator 312b and RF port 348 of bias generator 312b communicate, by way of nonlimiting example, a signal indicating one or more of voltage, current, or power output by the respective generator. By way of nonlimiting example, time-varying RF signals, such as sinusoidal voltage, current, or power signals may be communicated. In various configurations, one or multiple communication links 358 link signal port 344 and signal port 348. In various configurations, communication between signal port 344 and signal port 348 may occur via analog or digital communication.

In various configurations, a control signal communicated via communications link 358 is substantially the same as the control signal controlling source generator 312a. In various other configurations, the control signal communicated via communications link 358 is the same as the control signal controlling source generator 312a, but is phase shifted within source generator 312a in accordance with a requested phase shift generated by bias generator 312b. Thus, in various configurations, source generator 312a and bias generator 312b are driven by substantially identical control signals or by substantially identical control signals phase shifted by a predetermined amount.

In various configurations, power supply system 310 may include multiple source generators 312a and multiple bias generators 312b. By way of nonlimiting example, a plurality of source generators 312a, 312a′, 312a″, . . . , 312aⁿ can be arranged to provide a plurality of output power signals to one or more source electrodes of load 332. Similarly, a plurality of bias generators 312b, 312b′, 312b″, . . . , 312bⁿ may provide a plurality of output power signals to a plurality of bias electrodes of load 332. When source generator 312a and bias generator 312b are configured to include a plurality of respective source generators or bias generators, each generator will output a separate signal to a corresponding plurality of matching networks 318a, 318b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

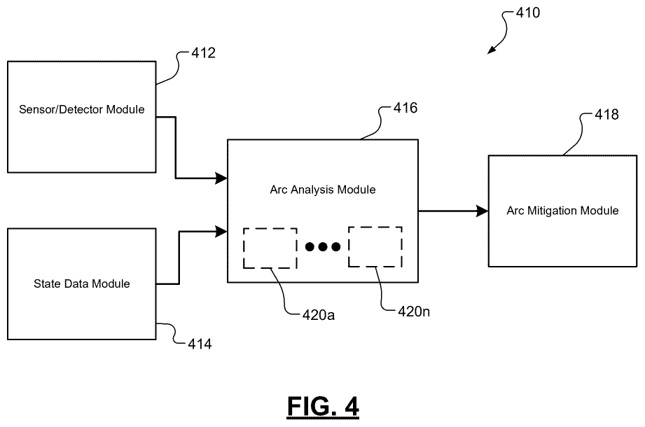

FIG. 4 shows a schematic block diagram of an arc detection and mitigation system 410 arranged in accordance with the present disclosure. Arc detection and mitigation system 410 includes a sensor/detector module 412, a state data module 414, and arc analysis module 416, and an arc mitigation module 418. Sensor/detector module 412 outputs sensed or determined electrical parameters, characteristics, or other measurement-based data to arc analysis module 416. Sensor/detector module 412, in various nonlimiting examples, outputs voltage and current information, such as may be obtained using the sensors described above in FIG. 3. In various nonlimiting examples, sensor/detector module 412 outputs gradients obtained from the derivative of sensed voltage and current to arc analysis module 416. In various other nonlimiting examples, sensor/detection module 412 outputs determined energy values. In various other nonlimiting examples, sensor/detector module 412 outputs a gradient of power such as a power value obtained by the product of voltage and current. In various other nonlimiting examples, sensor/detection module 412 outputs other processed values, such as reverse power, forward power, active power, reactive power, reflection coefficient (Γ), or the square of the magnitude of the reflection coefficient (|Γ|²) . It should be noted that sensor/detection module 412 may include one or a plurality of sensing and detecting devices and be configured to output any one of or a plurality of the sensed or determined electrical parameters, characteristics, or other measurement-based data described herein. While the description herein enumerates multiple nonlimiting examples of sensed or determined electrical parameters, characteristics, or other values output by sensor/detector module 412, sensor/detector module 412 may output other electrical parameters, characteristics, or values.

State data module 414 outputs current or historical state data to arc analysis module 416. In various nonlimiting examples, state data module 414 can output current or historical data related to one or more measured or commanded power levels, measured or commanded pulsing information, timestamp information, or recipe information, such as a command history. In various configurations, state data may include one or a plurality of commands from a host or subsidiary controller to the RF generator through any communication interface, analog, digital, or other. In various nonlimiting examples, pulsing information can include repetition rate, duty cycle, ramp rates between setpoints, and the like. In various other nonlimiting examples, state data module 414 can further output current or historical data related to measured or commanded pulsed DC frequency and duty cycle data or information, control loop statistics, recipe data provided regarding the semiconductor manufacturing process. In various other nonlimiting examples, state data module 414 can further output current or historical data as described herein shared between multiple power generators or power sources of a plasma processing system. In various other nonlimiting examples, state data module 414 can further output current or historical data related to matching networks of the plasma processing system. It should be noted that state data module 414 may be configured to output any one of or a plurality of the current or historical state data described herein. While the description herein enumerates multiple nonlimiting examples of current or historical state data output by state data module 414, state data module 414 may output other current or historical state data.

Arc analysis module 416 receives input from sensor/detector module 412 and state data module 414 and determines whether an arc has occurred and whether an adjustment should be made to the system in order to mitigate the identified arc. Arc analysis module 416 includes a plurality of arc detection sources 420a, . . . , 420n, where each arc detection source detects an arc. In various configurations, each arc detection source 420a, . . . , 420n detects a particular arc. In various other configurations, each arc detection source 420a, . . . , 420n detects a particular arc or detects the same arc as an other arc detection source 420a, . . . , 420n using a different methodology.

Arc analysis module 416 performs multiple functions, including in various nonlimiting examples, assigning weights to input received from sensor/detector module 412. In various configurations, arc analysis module 416 accumulates input or votes from various arc detection sources 420a, . . . , 420n. In various configurations, arc analysis module 416 combines current and historical state data received from state data module 414 with the input received from sensor/detector module 412 to augment typical arc detection processes. Arc analysis module 416 determines a mitigation response in accordance with one or more of the weighted, tallied, and combined inputs. In various configurations, arc analysis module 416 also determines and stores arc statistics, which may further be used in order to determine the existence of an arc or determine appropriate mitigation of the detected arc.

Arc mitigation module 418 executes various mitigation or response approaches to the detected arc. In various configurations, arc mitigation module 418 commands a power reduction of a power source or power generator in order to mitigate the arc. In various configurations, arc mitigation module 418 may indicate a system fault in accordance with the identified arc. In various configurations, arc mitigation module 418 may engage a protection circuit in response to the identified arc. In various configurations, arc mitigation module 418 takes no action in response to the identified arc, such as by way of nonlimiting example, if it is determined that the arc does not require a change in the operation of the system. It should be recognized that arc mitigation module 418 may execute any one of or a plurality of the possible responses in connection with one or a plurality of detected arcs.

In operation of arc detection and mitigation system 410, different types of arcs may be detected more reliably using specific detection sources or techniques, such as a specific arc detection sources 420a, . . . , 420n. By way of nonlimiting example, a power gradient detection approach may be able to identify equipment arcs, but an energy-based detection may be better suited to identify micro-arcs. Present arc detection systems do not combine multiple detection approaches to extend the arc detection capabilities to multiple types of arcs occurring within the same system. According to various configurations, information from multiple arc detection sources 420a, . . . , 420n provides arc analysis module 416 with more information about the arc event, enabling tuning of the arc mitigation response. By way of nonlimiting example, arc detection and mitigation system 410 may be configured to differentiate between different classes of arcs as described in FIG. 2 by having arc detection sources 420a, . . . , 420n trigger for an arc event simultaneously.

In various configurations, arc analysis module 416 implements various rules, thresholds, weighting, and voting criteria for determining whether an arc has occurred. In one nonlimiting example, a first arc detection source 420x, and a second arc detection source 420y, must both agree that an arc is occurring before triggering a mitigation event. In various configurations, first arc detection source 420x and second arc detection source 420y may be configured similarly. In various other configurations, first arc detection source 420x and second arc detection source 420y may be configured differently to detect the same type of arc. In various configurations, first arc detection source 420x and second arc detection source 420y may be configured to generate confidence scores, and the confidence scores can be compared pursuant to determining whether an arc has occurred. In various configurations and by way of nonlimiting example, first arc detection source 420x may be required to generate at least a predetermined (90% in one nonlimiting example) confidence of an arc, and second arc detection source 420y may be required to generate at least a predetermined (50% in one nonlimiting example) confidence of an arc prior to indicating that mitigation should occur. In various nonlimiting examples, the first arc and the second arc may be the same or different types of arcs. Further, in various configurations, lookup tables or decision trees could be used to encode such arc determination criteria. In various other configurations, if first arc detection source 420x is triggered and second arc detection source 420y is not triggered, arc analysis module 416 may command a relatively small power reduction to mitigate the detected arc.

In various configurations, each one of arc detection sources 420a, . . . , 420n can determine a magnitude of a detected arc, such as, by way of nonlimiting example, magnitudes 1 through 10. In various configurations, when multiple sources report arcs simultaneously, arc analysis module 416 may require that the cumulative magnitude of all the sources be greater than a predetermined user-defined cumulative magnitude before triggering mitigation. In various other configurations, arc analysis module 416 may implement a Bayesian approach to leverage individual outputs of arc detection sources 420a, . . . , 420n to generate a joint probability of a particular class of arc having occurred. The individual outputs of arc detection sources 420a, . . . , 420n can include a binary occurrence arc indicator, such as true or false, and an optional or required confidence score.

As described above, state data module 414 provides state data information to arc analysis module 416. Providing state data to arc analysis module 416 enhances the capability of arc analysis module 416 to accurately identify an arc event, classify the arc event, and determine the appropriate mitigation response. Thus, providing state data to arc analysis module 416 increases the flexibility of arc analysis module 416 to detect arcs. State data enables further understanding of the event detected by arc detection sources 420a, . . . , 420n. Further, operation of arc detection sources 420a, . . . , 420n can be enhanced as system designers identify state data that improves the identification of particular arcs. In various configurations and by way of nonlimiting example, if a pulsing repetition rate or other information of the generator or power supply is not included in the state data, the omitted repetition rate or other information can be added by system designers. Arc analysis module 414 could use the repetition rate or other information to modify the mitigation technique, such as adjusting the mitigation RF power reduction length.

In various configurations, in a first nonlimiting example, if first arc detection source 420x is triggered and second arc detection source 420y is triggered within 10 microseconds or some predetermined time, arc analysis module 416 may determine that an equipment arc has occurred and that the power sources of the plasma processing system should be disabled. In various other nonlimiting examples, if an arc event is detected within a predetermined time of the power source or power supply turning on turning on, arc analysis module 416 may command a significant mitigation response.

In various other nonlimiting examples, if the detected arc event is correlated with a specific semiconductor manufacturing the recipe command, arc analysis module 416 may determine that no mitigation response is required. In various other nonlimiting examples, if the proportional-integral-derivative (PID) control loop from the power supply or power generator control system has not yet reached steady state, arc analysis module 416 may determine that no mitigation response is required. In various other nonlimiting examples, if the reactive elements of the matching network are in a predetermined position, arc analysis module 416 may command issue a mitigation response that extends over a prolonged time.

In various other nonlimiting examples, arc analysis module 416 may be configured to adjust when the semiconductor manufacturing tool provides feedback that indicates the level of susceptibility to arcing during a particular phase of the semiconductor manufacturing recipe. By way of nonlimiting example, the semiconductor manufacturing tool may indicate that the manufacturing tool is entering a mode of operation where an arc is more likely to occur along with a time period during which the level of susceptibility to an arc is greater. In various nonlimiting examples, specific commands that convey sensitivity information, along with temporal information, such as how long to maintain the modified sensitivity, include a command that sets the arc detection sensitivity level and time duration to maintain the provided sensitivity level or a command that sets the arc detection sensitivity level indefinitely. In one nonlimiting example, the arc detection sensitivity can be turned off for a specified duration if the customer does not require arc detection during a particular section of the recipe.

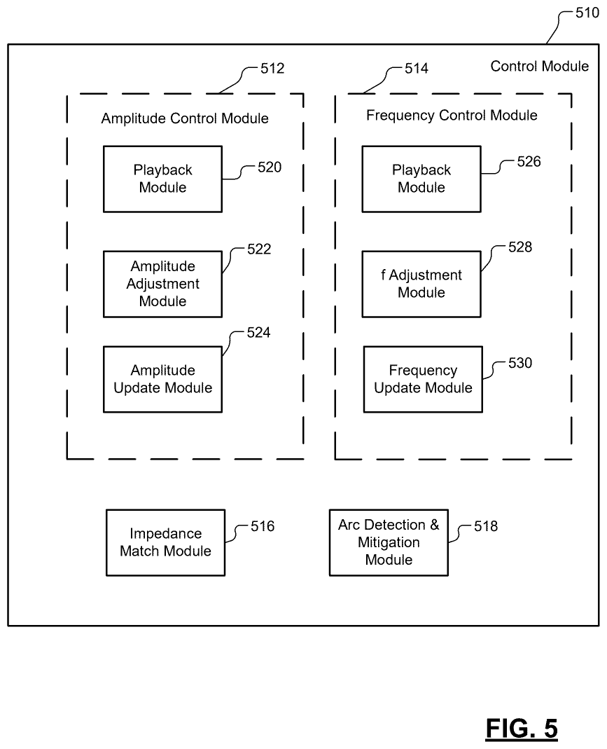

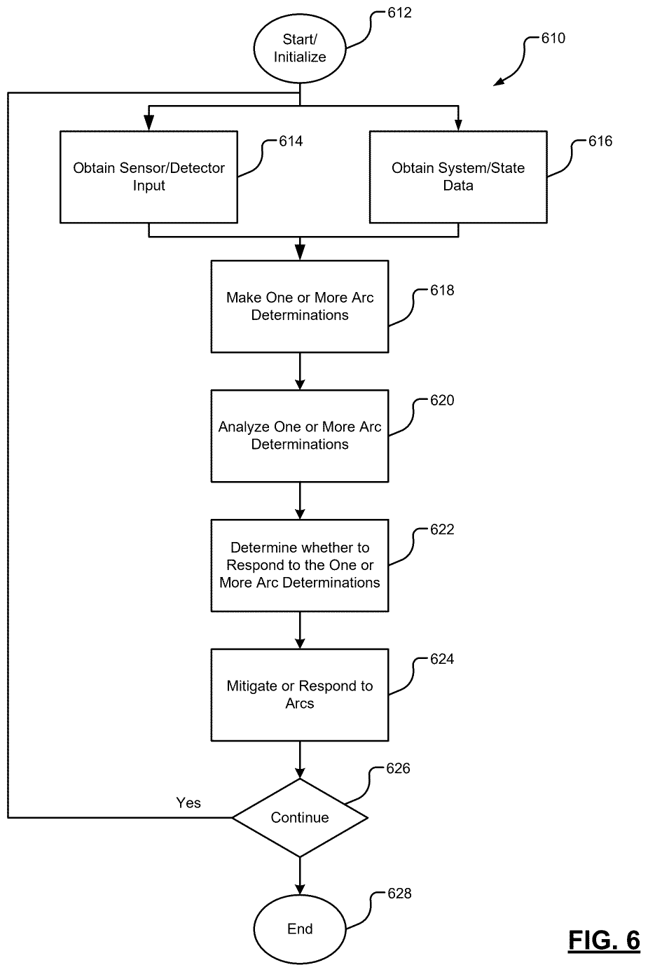

FIG. 5 incorporates various components of FIGS. 1-4. Control module 510 may include amplitude control module section 512, frequency control module section 514, impedance match module section 516, and arc detection and mitigation section 518. Amplitude control module section 512 may include one or more of playback module 520, amplitude adjustment module 522, and amplitude update module 524. Frequency control module section 514 may include one or more of playback module 526, frequency adjustment module 528, and frequency update module 530. Impedance match module section 516 may include a frequency control section or a reactive element control section. Arc detection and mitigation section 518 may include control sections to implement the various configurations described above. In various configurations, control module 510 includes one or a plurality of processors that execute code associated with the module sections or modules 510, 512, 514, 516, 518, 520, 522, 524, 526, 528, and 530. Operation of the module sections or modules, 512, 514, 516, 518, 520, 522, 524, 526, and 530 is described below with respect to the method of FIG. 6.

For further defined structure of controllers 320a, 320b, and 320′ of FIG. 3, see the below provided flow chart of FIG. 6 and the below provided definition for the term “module”. The systems disclosed herein may be operated using numerous methods, examples, and various control system methods of which are illustrated in FIG. 3. Although the following operations are primarily described with respect to the implementations of FIG. 3, the operations may be easily modified to apply to other implementations of the present disclosure. The operations may be iteratively performed. Although the following operations are shown and primarily described as being performed sequentially, one or more of the following operations may be performed while one or more of the other operations are being performed.

FIG. 6 shows a flow chart of a control system 610 for performing mode-based impedance control for, for example, the power delivery systems of FIGS. 1-5. Control begins at 612 which initializes operation of the system and proceeds to 614 and 616, which in various configurations, operate in parallel. At 614, sensor and detector output is obtained, and at 616, system/state data is obtained. Control proceeds to 618 which makes one or a plurality of arc determinations and outputs one or a plurality of arc detection signals, where arc determinations may be generated by one or a plurality of arc detector modules, such as arc detection sources 420a, . . . , 420n. Control proceeds 620 and the one or a plurality of arc detection signals are analyzed, where the analysis may include factors described above in connection with arc analysis module 416. Control proceeds to 622 which determines whether to respond to the one or a plurality of arcs in accordance with the analysis at 620. Control proceeds to 624 which mitigates or responds to the arcs of 622 as described above. Control proceeds to 626 which determines whether to continue the arc detection and mitigation process. If the arc determination and mitigation process is to continue, control proceeds 614 and 616. If the arc determination and mitigation process is to terminate, control proceeds to 628 were the process ends.

The system of the present disclosure may provide one or more of the following benefits, including increased arc detection reliability and increased capability to characterize arcs. The system of the present disclosure may further provide the capability to change mitigation response based on arc characteristics or state data, thus reducing the probability of process interruption or damage. The system of the present disclosure may further leverage machine learning to further enhance and generalize arc detection, especially with regards to the general state data provided to the detection module.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “non-empty set” may be used to indicate exclusion of the empty set—in other words, a non-empty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A controller for an arc detection system comprising:
at least one arc detector module configured to output at least one arc detection signal in a plasma processing system; and
an arc analysis module configured to receive the at least one arc detection signal, to determine if at least one arc is present in the plasma processing system based on the at least one arc detection signal, and to generate an arc mitigation signal in accordance with the at least one arc.

2. The controller of claim 1 further comprising a state data module configured to obtain information about at least one state of the plasma processing system, wherein the arc analysis module determines if the at least one arc is present in the plasma processing system additionally based on the at least one state of the plasma processing system.

3. The controller of claim 2 wherein the information about at least one state of the plasma processing system comprises at least one of current or historical data related to one or more measured or commanded power levels, measured or commanded pulsing information, pulse repetition rate, pulse duty cycle, pulse ramp rate between setpoints, timestamp information, recipe information, pulsed DC frequency, pulsed DC duty cycle, control loop statistics, recipe data, data shared between multiple power generators or power sources of a plasma processing system, and matching network data.

4. The controller of claim 1 further comprising an arc mitigation module configured to receive commands from the arc analysis module and generate commands to at least one of mitigate the at least one arc or indicate a fault, or take no action.

5. The controller of claim 4 wherein the arc mitigation module at least one of commands an adjustment to an electrical component of the plasma processing system, indicates a system fault, or engages a protection circuit.

6. The controller of claim 1 wherein the at least one arc detector module is configured to output the arc detection signal in accordance with at least one sensed, measured, or determined electrical parameter or characteristic of the plasma processing system, including at least one of voltage, current, reverse power, forward power, active power, reactive power, gradients of at least one of voltage, current, energy, gradients of at least one of power, reverse power, forward power, active power, or reactive power, reflection coefficient, or a square of a magnitude of a reflection coefficient.

7. The controller of claim 1 wherein the at least one arc detector module includes a plurality of arc detection sources, wherein the at least one arc detection signal includes a plurality of arc detection signals and each one of the plurality of arc detection sources generates a respective one of the plurality of arc detection signals.

8. The controller of claim 7 wherein the arc analysis module assigns a weight to each arc detection signal of the plurality of arc detection signals, and the weights of the plurality of arc detection signals are one of compared, tallied, or accumulated to determine whether to respond to the at least one arc.

9. The controller of claim 1 wherein the arc analysis module is configured to determine whether to respond to the determination that at least one arc is present in accordance with the arc detection signal and information about at least one state of the plasma processing system.

10. The controller of claim 1 wherein the at least one arc includes a pair of arcs and the arc analysis module determines a time between the pair of arcs and triggers arc mitigation if the time is less than a predetermined time.

11. A non-transitory computer-readable medium storing instructions, the instructions comprising:
obtaining at least one arc detection signal in a plasma processing system; and
receiving the at least one arc detection signal, determining if at least one arc is present in the plasma processing system based on the at least one arc detection signal, and generating an arc mitigation signal in accordance with the at least one arc.

12. The non-transitory computer-readable medium storing instructions of claim 11, the instructions comprising obtaining information about at least one state of the plasma processing system, wherein determining if the at least one arc is present in the plasma processing system is additional based on the at least one state of the plasma processing system.

13. The non-transitory computer-readable medium storing instructions of claim 12 wherein the information about at least one state of the plasma processing system comprises at least one of current or historical data related to one or more measured or commanded power levels, measured or commanded pulsing information, pulse repetition rate, pulse duty cycle, pulse ramp rate between setpoints, timestamp information, recipe information, pulsed DC frequency, pulsed DC duty cycle, control loop statistics, recipe data, data shared between multiple power generators or power sources of a plasma processing system, and matching network data.

14. The non-transitory computer-readable medium storing instructions of claim 11, the instructions comprising receiving the arc mitigation signal and generating commands to at least one of mitigate the at least one arc or indicate a fault, or take no action.

15. The non-transitory computer-readable medium storing instructions of claim 14, wherein mitigating the at least one arc further comprises at least one of commanding a power adjustment to an electrical component of the plasma processing system or engaging a protection circuit.

16. The non-transitory computer-readable medium storing instructions of claim 11 wherein the at least one arc detection signal varies in accordance with at least one sensed, measured, or determined electrical parameter or characteristic of a plasma processing system including at least one of voltage, current, reverse power, forward power, active power, reactive power, gradients of at least one of voltage, current, energy, gradients of at least one of power, reverse power, forward power, active power, or reactive power, reflection coefficient, or a square of a magnitude of a reflection coefficient.

17. The non-transitory computer-readable medium storing instructions of claim 11, wherein the at least one arc detection signal includes a plurality of arc detections signals and the instructions further comprise instructions for obtaining the plurality of arc detection signals using two different approaches.

18. The non-transitory computer-readable medium storing instructions of claim 17, wherein the instructions further comprise instructions for assigning a weight to each arc detection signal of the plurality of arc detection signals and for one of comparing, tallying, or accumulating the weights to determine whether to respond to the at least one arc.

19. The non-transitory computer-readable medium storing instructions of claim 11, wherein the instructions further comprise determining whether to respond to the determination that at least one arc is present in accordance with the arc detection signal and information about at least one state of the plasma processing system.

20. The non-transitory computer-readable medium storing instructions of claim 11, wherein the at least one arc includes a pair of arcs and the instructions further comprise instructions for determining a time between the pair of arcs and triggering arc mitigation if the time is less than a predetermined time.
